(19) United States
(12) Patent Application Publication
(10) Pub. No.: US 2023/0408194 A1
(43) Pub. Date: Dec. 21, 2023

(54) SUBSTRATE PROCESSING APPARATUS AND SUBSTRATE PROCESSING METHOD

(71) Applicant: SEMES CO., LTD., Cheonan-si (KR)

(72) Inventor: Haewon Choi, Daejeon-si (KR)

(73) Assignee: SEMES CO., LTD., Cheonan-si (KR)

(21) Appl. No.: 18/205,525

(22) Filed: Jun. 3, 2023

(30) Foreign Application Priority Data
Jun. 15, 2022 (KR) 10-2022-0073063
Jul. 21, 2022 (KR) 10-2022-0090609

(51) Int. Cl. F26B 5/00

(52) U.S. Cl. CPC F26B 5/005; H01L 21/67034

(57) ABSTRACT

A substrate processing apparatus includes a body having a processing space configured to pressurize a drying process fluid at a supercritical pressure therein, a fluid supply unit configured to supply the drying process fluid to the processing space, and a discharge unit configured to discharge the drying process fluid from inside the processing space, wherein the discharge unit includes a discharge line coupled to the body, and a sampling unit including a sampling line branched from a rear end area of the discharge line and configured to extract a sampling fluid, and a detector arranged in the sampling line and configured to analyze the sampling fluid.

### CROSS-REFERENCE TO RELATED APPLICATIONS

This application is based on and claims priority under 35 U.S.C. § 119 to Korean Patent Application Nos. 10-2022-0073063, filed on Jun. 15, 2022, and 10-2022-0090609, filed on Jul. 21, 2022, in the Korean Intellectual Property Office, the disclosures of each of which are incorporated by reference herein in their entireties.

### BACKGROUND

### 1. Field

The disclosure relates to a substrate processing apparatus and a substrate processing method, and more particularly, to a substrate processing apparatus using a supercritical drying process fluid (that is, supercritical carbon dioxide).

### 2. Description of the Related Art

In general, a semiconductor device is manufactured from a substrate, such as a wafer. In particular, a semiconductor device is manufactured by forming a fine circuit pattern on an upper surface of a substrate by performing a deposition process, a photolithography process, an etching process, or the like.

The upper surface of the substrate on which the circuit pattern is formed may be contaminated with various foreign materials while the above processes are performed, and thus a cleaning process for removing the foreign materials and a drying process after cleaning may be required.

Recently, a supercritical drying process fluid is used in a process of cleaning a substrate. According to an example, a cleaning process is performed in such a way that an upper surface of a substrate is cleaned through a volatile organic compound, and then the volatile organic compound remaining on the substrate is removed by supplying carbon dioxide (CO₂) to the upper surface of the substrate in a supercritical state.

After using a cleaning and developing fluid on a substrate by a cleaning and developing (semiconductor liquid processing) apparatus, a drying process is performed to remove the fluid on the substrate. As a pattern on a substrate has recently become finer, a drying process using supercritical carbon dioxide (CO₂) may be performed to prevent pattern collapse. As such, when the drying process using the supercritical carbon dioxide is performed, a drying process state cannot be known by directly monitoring the inside of a supercritical carbon dioxide drying processing apparatus until the process is finished, and thus it is difficult to control conditions, such as a supply amount and a discharge amount of the cleaning and developing fluid, a process time, or the like. When the process is excessively performed by continuously supplying carbon dioxide to remove and dry the cleaning and developing fluid from the substrate even after the purpose of the process has been achieved, production costs and processing time increase, resulting in lower yields. On the other hand, when the process is finished before achieving the purpose of the process, this causes cleaning or developing defects due to insufficient drying.

### SUMMARY

Provided are a substrate processing method and a substrate processing apparatus, which may improve supercritical drying efficiency with respect to removing and drying a process treatment solution (cleaning solution or developing solution) by using a supercritical fluid after cleaning and developing a substrate.

According to an aspect of the disclosure, optimal process conditions are detected for when a substrate is supercritically dried and treated by using a supercritical fluid.

Additional aspects will be set forth in part in the description which follows and, in part, will be apparent from the description, or may be learned by practice of the presented embodiments of the disclosure.

According to an aspect of the disclosure, a substrate processing apparatus includes a body having a processing space configured to pressurize a drying process fluid at a supercritical pressure therein, a fluid supply unit configured to supply the drying process fluid to the processing space, and a discharge unit configured to discharge the drying process fluid from inside the processing space, wherein the discharge unit includes a discharge line coupled to the body, and a sampling unit including a sampling line branched from a rear end area of the discharge line and configured to extract a sampling fluid, and a detector arranged in the sampling line and configured to analyze the sampling fluid.

The substrate processing apparatus further includes a controller configured to control whether the fluid supply unit is operated and whether the discharge unit is operated, the controller being further configured to receive information about the sampling fluid from the detector to control an operation of each of the fluid supply unit and the discharge unit.

The controller is further configured to stop supply of the drying process fluid and discharge the drying process fluid when a concentration of an object to be detected by the detector is detected to be equal to or less than a set value.

The controller is further configured to stop supply of the drying process fluid and discharge the drying process fluid when the fluid supply unit supplies the drying process fluid by a number of times equal to or greater than a set number of times.

The sampling fluid includes the drying process fluid and an object to be detected, and the detector is further configured to remove the drying process fluid from the sampling fluid and detect the object to be detected.

The detector is further configured to detect at least one of a component, concentration, and number of particles of an object to be detected.

The object to be detected includes a volatile organic compound.

An amount of the extracted sampling fluid is within 0.0001% of a discharge amount of a discharge fluid discharged through the discharge line.

According to another aspect of the disclosure, a substrate processing apparatus includes a body having a processing space in which a cleaning processing operation is performed, a support unit configured to support a substrate inside the processing space, a fluid supply unit configured to supply a drying process fluid to the processing space, a discharge unit configured to discharge the drying process fluid inside the processing space, and a controller configured to control whether the fluid supply unit is operated and whether the discharge unit is operated, wherein the discharge unit includes a discharge line coupled to the body, a sampling unit including a sampling line branched from a rear end area of the discharge line and configured to extract a sampling fluid, and a detector arranged in the sampling line and configured to analyze the sampling fluid, wherein the controller is further configured to control to supply the drying process fluid to the processing space, and control to discharge the drying process fluid from inside the processing space.

The controller is further configured to receive information about the sampling fluid from the detector to control an operation of each of the fluid supply unit and the discharge unit.

The substrate processing apparatus further includes a first valve at a front end of the discharge line, wherein the controller opens the first valve when the drying process fluid is discharged.

The substrate processing apparatus further includes a second valve inside the sampling unit, wherein the controller opens the second valve when a portion of the drying process fluid is introduced into the sampling unit.

The drying process fluid inside the processing space includes a supercritical fluid.

According to another aspect of the disclosure, a substrate processing method includes a pressure raising operation of supplying a drying process fluid into a processing space, an operation of repeating supply and discharge of the drying process fluid with respect to an inside of the processing space, a final discharge operation of discharging the drying process fluid from inside the processing space, and a sampling operation of extracting and detecting a portion of the drying process fluid discharged by a sampling unit branched from a rear end area of a discharge line connected to the processing space, wherein the operation of repeating supply and discharge of the drying process fluid is ended and the final discharge operation is started based on information detected by the sampling unit.

The operation of repeating supply and discharge of the drying process fluid is ended when a concentration of an object to be detected is detected to be equal to or less than a set value, or when a number of times the drying process fluid is supplied is equal to or greater than a set value.

The sampling operation includes detecting information about a sampling fluid, the sampling fluid comprises the drying process fluid and an object to be detected, and at least one of a component, concentration, and amount of the sampling fluid is detected.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a substrate processing system according to an embodiment;

FIG. 2 is a cross-sectional view schematically illustrating an embodiment of a liquid processing apparatus according to an embodiment;

FIG. 3 is a cross-sectional view illustrating an arrangement of components of a cleaning apparatus according to an embodiment;

FIG. 4 is a layout view illustrating a cleaning apparatus including a discharge unit, according to an embodiment;

FIGS. 5A and 5B show a graph showing a change in pressure over time using a drying process fluid, and a graph showing a change in a detection amount of an object to be detected over time, according to an embodiment; and

FIG. 6 is a flowchart illustrating a method of determining an end point of a process by analyzing a sampling fluid, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The disclosure will now be described more fully with reference to the accompanying drawings, in which exemplary embodiments of the disclosure are shown. Advantages and features of the disclosure, and methods for achieving the same, will become clear with reference to the embodiments to be described below in detail in conjunction with the accompanying drawings. The disclosure may, however, be embodied in many different forms and should not be construed as being limited to the exemplary embodiments set forth herein. Rather, these embodiments are provided so that this disclosure will be thorough and complete, and will fully convey the scope of the disclosure to one of ordinary skill in the art. The disclosure is only defined by the scope of the claims. Like reference numerals in the drawings denote like elements.

It will be understood that when an element or layer is referred to as being “on” another element or layer, the element or layer can be directly on the other element or layer or intervening components may be present thereon. On the other hand, when an element is referred to as being “directly on” another element, no intervening components may be present therebetween.

The spatially relative terms “below”, “beneath”, “lower”, “above”, “upper”, etc. can be used to easily describe the interrelationships of one element or component with another element or component as shown in the drawing. Spatially relative terms should be understood as including different orientations of elements in use or operation in addition to the orientations shown in the drawings. For example, when elements shown in the drawings are reversed, an element described as “below” or “beneath” another element may be placed “above” the other element. Thus, the exemplary term “below” may include directions of both below and above. Elements may also be oriented in other orientations, and thus spatially relative terms may be interpreted according to orientations.

While such terms as “first,” “second,” etc., may be used to describe various elements, components, and/or sections, such elements, components, and/or sections must not be limited to the above terms. The above terms are used only to distinguish one element, component, or section from another. Accordingly, in the technical spirit of the disclosure, a first element, a first component, or a first section may be a second element, a second component, or a second component.

The terms used in the present disclosure are merely used to describe particular embodiments, and are not intended to limit the disclosure. An expression used in the singular encompasses the expression of the plural, unless it has a clearly different meaning in the context. In the present specification, it is to be understood that terms such as “including,” “having,” and “comprising” are intended to indicate the existence of the components, steps, operations, and/or elements disclosed in the specification, and are not intended to preclude the possibility that one or more other components, steps, operations, and/or elements may exist or may be added.

Unless otherwise defined, all terms (including technical and scientific terms) used in this specification may be used in a meaning commonly understood by those of ordinary skill in the art to which the disclosure belongs. In addition, terms defined in commonly used dictionaries are not interpreted ideally or excessively unless explicitly specifically defined.

Hereinafter, the disclosure will be described in detail by explaining embodiments of the disclosure with reference to the attached drawings. Like reference numerals in the drawings denote like elements, and thus their descriptions will be omitted.

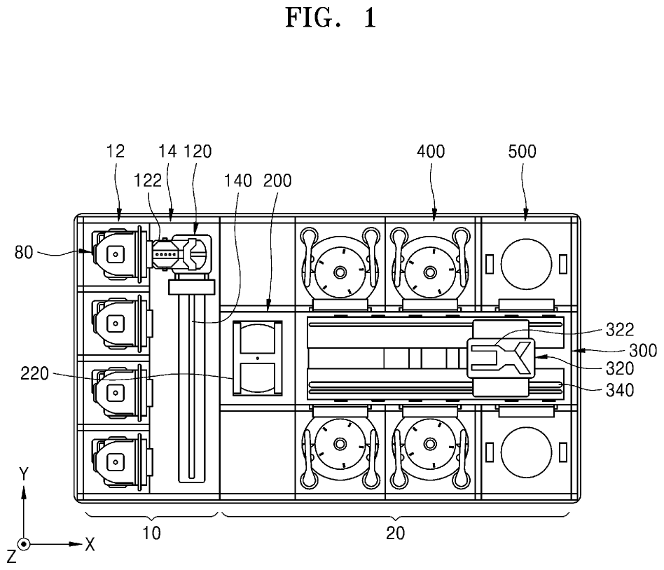

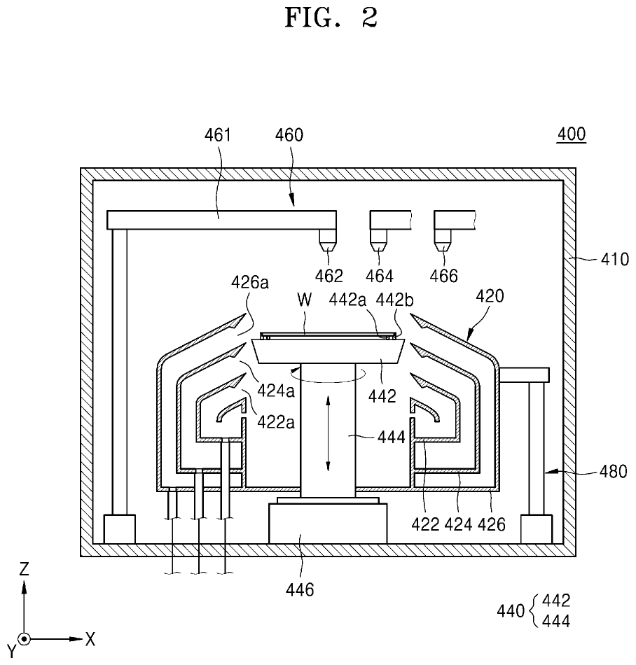

FIG. 1 is a plan view schematically illustrating a substrate processing system according to an embodiment. FIG. 2 is a cross-sectional view schematically illustrating an embodiment of a liquid processing apparatus according to an embodiment.

Referring to FIGS. 1 and 2, the substrate processing system may include an index module 10 and a processing module 20. According to an embodiment, the index module 10 and the processing module 20 may be arranged in one direction. Hereinafter, the direction in which the index module 10 and the processing module 20 are arranged is referred to as a first horizontal direction (X direction). When viewed from the above, a direction perpendicular to the first horizontal direction is referred to as a second horizontal direction (Y direction), and a direction perpendicular to both the first horizontal direction (X direction) and the second horizontal direction (Y direction) is referred to as a vertical direction (Z direction).

The index module 10 transfers a substrate W from a container 80 in which the substrate W is stored to the processing module 20, and stores the substrate W that has been processed by the processing module 20 into the container 80. For example, a longitudinal direction of the index module 10 is provided as the second horizontal direction (Y direction). The index module 10 includes a loadport 12 and an index frame 14. With respect to the index frame 14, the loadport 12 is positioned on the opposite side of the processing module 20. The container 80 in which substrates W are stored is placed in the loadport 12. A plurality of loadports 12 may be provided, and the plurality of loadports 12 may be arranged in the second horizontal direction (Y direction).

The container 80 may be, for example, an airtight container, such as a front open unified pod (FOUP). The container 80 may be placed in the loadport 12 by an operator or a transportation unit (not shown), such as an overhead transfer, an overhead conveyor, or an automatic guided vehicle.

An index robot 120 is provided in the index frame 14. A guide rail 140, of which a longitudinal direction is provided as the second horizontal direction (Y direction), may be provided in the index frame 14, and the index robot 120 may be provided on the guide rail 140. The index robot 120 may include a hand 122 on which the substrate W is placed, and the hand 122 may move forward and backward, rotate with respect to the vertical direction (Z direction), and move in the vertical direction (Z direction). A plurality of hands 122 may be provided to be spaced apart from each other in the vertical direction (Z direction), and the plurality of hands 122 may move forward and backward independently of each other.

The processing module 20 includes a buffer unit 200, a transfer apparatus 300, a liquid processing apparatus 400, and a post cleaning drying processing apparatus 500. The buffer unit 200 provides a space in which the substrate W carried into the processing module 20 and the substrate W transported out of the processing module 20 temporarily stay. The liquid processing apparatus 400 performs a liquid processing process of liquid-processing the substrate W by supplying a liquid onto the substrate W. The post cleaning drying processing apparatus 500 performs a drying process of removing liquid remaining on the substrate W. The transfer apparatus 300 transfers the substrate W between the buffer unit 200, the liquid processing apparatus 400, and the post cleaning drying processing apparatus 500.

A longitudinal direction of the transfer apparatus 300 may be provided as the first horizontal direction (X direction). The buffer unit 200 may be between the index module 10 and the transfer apparatus 300. The liquid processing apparatus 400 and the post cleaning drying processing apparatus 500 may be arranged on a side portion of the transfer apparatus 300. The transfer apparatus 300, the liquid processing apparatus 400 and/or the post cleaning drying processing apparatus 500 may be arranged in the first horizontal direction and/or the second horizontal direction (X direction and/or Y direction). The buffer unit 200 may be on one end of the transfer apparatus 300.

According to an embodiment, liquid processing apparatuses 400 may be arranged on both sides of the transfer apparatus 300, post cleaning drying processing apparatuses 500 may be arranged on the both sides of the transfer apparatus 300, and the liquid processing apparatuses 400 may be arranged closer to the buffer unit 200 than the post cleaning drying processing apparatuses 500. On one side of the transfer apparatus 300, one or more liquid processing apparatuses 400 may be arranged in the first horizontal direction (X direction) and the vertical direction (Z direction). Also, on one side of the transfer apparatus 300, one or more post cleaning drying processing apparatuses 500 may be arranged in the first horizontal direction (X direction) and the vertical direction (Z direction). Unlike the above description, only the liquid processing apparatuses 400 may be provided on one side of the transfer apparatus 300, and only the post cleaning drying processing apparatuses 500 may be provided on the other side thereof.

The transfer apparatus 300 includes a transfer robot 320. In the transfer apparatus 300, a guide rail 340, of which a longitudinal direction is provided as the first horizontal direction (X direction), may be provided, and the transfer robot 320 may be provided to be movable on the guide rail 340. The transfer robot 320 may include a hand 322 on which the substrate W is placed, and the hand 322 may move forward and backward, rotate with respect to the vertical direction (Z direction), and move in the vertical direction (Z direction). A plurality of hands 322 may be provided to be spaced apart from each other in the vertical direction (Z direction), and the plurality of hands 322 may move forward and backward independently of each other.

The buffer unit 200 includes a plurality of buffers 220 on which each the substrate W is placed. The buffers 220 may be arranged to be spaced apart from each other in the vertical direction (Z direction). The buffer unit 200 may have a front face and a rear face, which are open. The front face of the buffer unit 200 is a surface facing the index module 10, and the rear face thereof is a surface facing the transfer apparatus 300. The index robot 120 may approach the buffer unit 200 through the front face thereof, and the transfer robot 320 may approach the buffer unit 200 through the rear face thereof.

The liquid processing apparatus 400 may include a housing 410, a cup 420, a support unit 440, a liquid supply unit 460, and an elevating-and-descending unit 480. The housing 410 is provided in a substantially rectangular parallelepiped shape. The cup 420, the support unit 440, and the liquid supply unit 460 may be arranged in the housing 410.

The cup 420 has a processing space with an open upper portion, and the substrate W is liquid-processed in the processing space. The support unit 440 supports the substrate W in the processing space. The liquid supply unit 460 supplies liquid onto the substrate W supported by the support unit 440. A plurality of types of liquid may be provided, and may be sequentially supplied onto the substrate W. The elevating-and-descending unit 480 adjusts the relative height between the cup 420 and the support unit 440.

According to an embodiment, the cup 420 includes a plurality of re-collect containers including first to third re-collect containers 422, 424, and 426. Each of the plurality of re-collect containers has a re-collect space for re-collecting liquid used in substrate processing. Each of the plurality of re-collect containers is provided in a ring shape surrounding the support unit 440. When a liquid processing process is performed, pre-processing liquid scattered by the rotation of the substrate W flows into the re-collect spaces through inlets including first to third 422a, 424a, and 426a of the plurality of re-collect containers, respectively. According to an embodiment, the cup 420 includes the first re-collect container 422, the second re-collect container 424, and the third re-collect container 426. The first re-collect container 422 is arranged to surround the support unit 440, the second re-collect container 424 is arranged to surround the first re-collect container 422, and the third re-collect container 426 is arranged to surround the second re-collect container 424. The second inlet 424a introducing liquid into the second re-collect container 424 may be positioned above the first inlet 422a introducing liquid into the first re-collect container 422, and the third inlet 426a introducing liquid into the third re-collect container 426 may be positioned above the second inlet 424a.

The support unit 440 includes a support plate 442 and a driving shaft 444. The support plate 442 may have an upper surface provided in a substantially circular shape, and may have a greater diameter that that of the substrate W. A support pin 442a supporting a rear surface of the substrate W is provided at a central portion of the support plate 442, and an upper end of the support pin 442a protrudes from the support plate 442 such that the substrate W is spaced apart from the support plate 442 by a certain distance. A chuck pin 442b is provided at an edge portion of the support plate 442. The chuck pin 442b is provided to protrude upward from the support plate 442, and supports a side portion of the substrate W such that the substrate W is not detached from the support unit 440, when the substrate W is rotated. The driving shaft 444 is driven by a driver 446, is connected to the center of a bottom surface of the substrate W, and rotates the support plate 442 with respect to a central axis of the support plate 442.

According to an embodiment, the liquid supply unit 460 includes a first nozzle 462, a second nozzle 464, and a third nozzle 466. The first nozzle 462 supplies a first liquid onto the substrate W. The first liquid may be a liquid that removes a film or foreign material remaining on the substrate W. The second nozzle 464 supplies a second liquid onto the substrate W. The second liquid may be a liquid that dissolves well in a third liquid. For example, the second liquid may be a liquid that dissolves better in the third liquid than the first liquid. The second liquid may be a liquid that t neutralizes the first liquid supplied onto the substrate W. Also, the second liquid may be a liquid that neutralizes the first liquid and at the same time dissolves better in the third liquid compared to the first liquid. According to an embodiment, the second liquid may be water. The third nozzle 466 supplies the third liquid onto the substrate W. The third liquid may be a liquid that dissolves well in a supercritical fluid (that is, a drying process fluid) used in the post cleaning drying processing apparatus 500. For example, the third liquid may be a liquid that dissolves better in a drying process fluid used in the post cleaning drying processing apparatus 500 compared to the second liquid. According to an embodiment, the third liquid may be an organic solvent. For example, the organic solvent may be a volatile organic compound. For example, the organic solvent may include n-butyl acetate (n-BA), propylene glycol methyl ether acetate (PGMEA), n-heptane, n-decane, dibutyl ether (DBE), isoamyl ether (TAB) and/or isopropyl alcohol (IPA). According to an embodiment, the drying process fluid may be carbon dioxide. The first nozzle 462, the second nozzle 464, and the third nozzle 466 may be supported by different arms 461, and each of the arms 461 may move independently. Optionally, the first nozzle 462, the second nozzle 464, and the third nozzle 466 may be mounted on the same arm and moved simultaneously.

The elevating-and-descending unit 480 moves the cup 420 in an up-and-down direction. A relative height between the cup 420 and the substrate W is changed by the up-and-down movement of the cup 420. Accordingly, the re-collect containers, including the first to third re-collect containers 422, 424, and 426, which re-collect the pre-processing liquid, are changed according to the type of liquid supplied to the substrate W, and thus liquids may be separately re-collected. Unlike the above description, the cup 420 may be fixedly installed, and the elevating-and-descending unit 480 may move the support unit 440 in the vertical direction (Z direction).

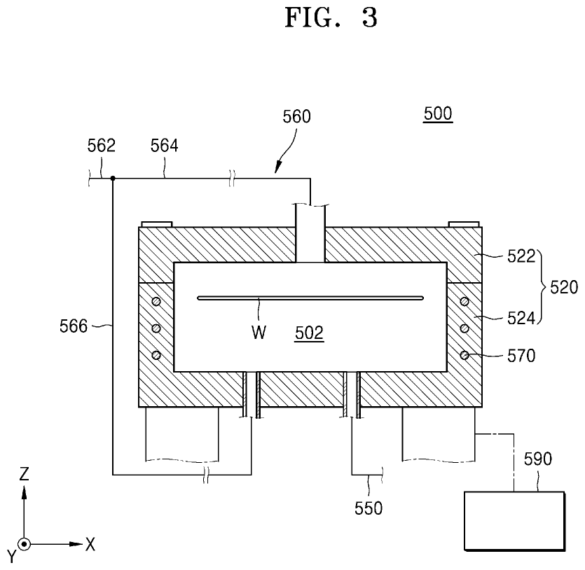

FIG. 3 is a cross-sectional view illustrating an arrangement of components of a cleaning apparatus according to an embodiment.

Referring to FIG. 3, the post cleaning drying processing apparatus 500 removes liquid on the substrate W by using a drying process fluid. The post cleaning drying processing apparatus 500 includes a body 520, a support body (not shown), a fluid supply unit 560, and a blocking plate (not shown). In FIG. 3, illustration of the support unit 440 (refer to FIG. 2) is omitted for convenience of description.

The body 520 provides a processing space 502 in which a cleaning process is performed. A drying process fluid inside the processing space 502 may be pressurized to a supercritical pressure. The body 520 includes an upper body 522 and a lower body 524, and the upper body 522 and the lower body 524 are combined with each other to provide the processing space 502 described above. The upper body 522 is provided on an upper portion of the lower body 524. The position of the upper body 522 may be fixed, and the lower body 524 may be elevated and descended by a driving member 590, such as a cylinder. When the lower body 524 is spaced apart from the upper body 522, the processing space 502 is opened, and at this time, the substrate W is carried in or transported out. During the process, the lower body 524 is in close contact with the upper body 522 so that the processing space 502 is sealed from the outside. The post cleaning drying processing apparatus 500 may include a heater 570. According to an embodiment, the heater 570 is inside a ball of the body 520. The heater 570 heats the processing space 502 of the body 520 so that a fluid supplied into an inner space of the body 520 maintains a supercritical state. Inside the processing space 502, an atmosphere is formed by the drying process fluid.

The support body supports the substrate W within the processing space 502 of the body 520. The support body includes a fixing rod (not shown) and a holder (not shown). The fixing rod is fixedly installed to the upper body 522 to protrude downward from a bottom surface of the upper body 522. A longitudinal direction of the fixing rod is provided as the vertical direction (Z direction). A plurality of fixing rods are provided and are spaced apart from each other. The plurality of fixing rods may be arranged so that the substrate W does not collide with the plurality of fixing rods when the substrate W is carried in or transported out of a space surrounded by the plurality of fixing rods. The holder is coupled to each of the plurality of fixing rods. The holder extends from a lower end of the fixing rod toward the space surrounded by the plurality of fixing rods. Due to the structure described above, an edge area of the substrate W carried into the processing space 502 of the body 520 is placed on the holder, and the entire area of an upper surface of the substrate W, a central area of the bottom surface of the substrate W, and a portion of an edge area of the bottom surface of the substrate W are exposed to the drying process fluid supplied to the processing space 502.

The fluid supply unit 560 supplies the drying process fluid to the processing space 502 of the body 520. According to an embodiment, the drying process fluid may be supplied to the processing space 502 in a supercritical state. On the contrary, the drying process fluid may be supplied to the processing space 502 in a gaseous state and may be phase-changed into a supercritical state within the processing space 502. According to an embodiment, the fluid supply unit 560 includes a main supply line 562, an upper branch line 564, and a lower branch line 566. The upper branch line 564 and the lower branch line 566 may branch from the main supply line 562. The upper branch line 564 is coupled to the upper body 522 to supply a drying process fluid to an upper portion of the substrate W placed on the support body. According to an embodiment, the upper branch line 564 is coupled to the center of the upper body 522. The lower branch line 566 is coupled to the lower body 524 to supply the drying process fluid to a lower portion of the substrate W placed on the support body. According to an embodiment, the lower branch line 566 may be coupled to the center of the lower body 524. A discharge unit 550 may be coupled to the lower body 524. When the lower branch line 566 is coupled to the center of the lower body 524, a discharge port of the discharge unit 550 may be biased in one horizontal direction from the center of the lower body 524. The drying process fluid in the processing space 502 of the body 520 may be discharged to the outside of the body 520 through the discharge unit 550.

The blocking plate may be arranged in the processing space 502 of the body 520. The blocking plate may be provided in a disk shape. The blocking plate is supported by a support (not shown) to be positioned at an upper portion of the body 520 to be spaced apart from the bottom surface of the body 520. The support is provided in a rod shape, and a plurality of supports are arranged to be spaced apart from each other by a certain distance. When viewed from the top, the blocking plate may overlap a supply port of the lower branch line 566 and an inlet of the discharge unit 550. The blocking plate may prevent the drying process fluid supplied through the lower branch line 566 from being discharged toward the substrate W to cause damage of the substrate W.

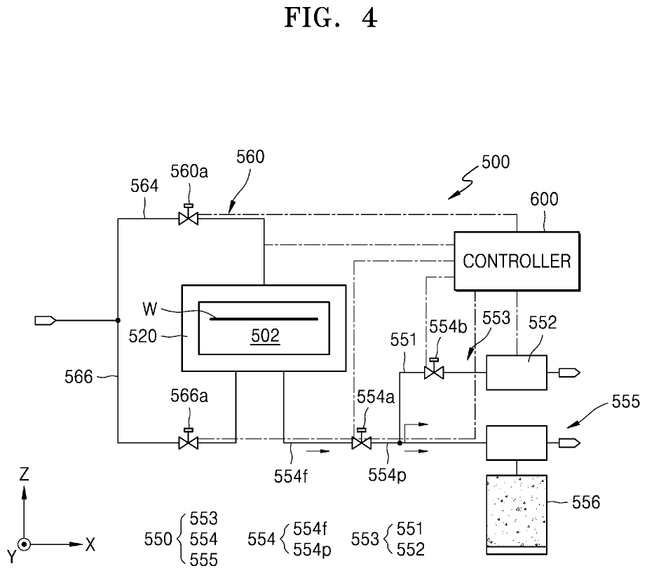

FIG. 4 is a layout view illustrating a cleaning apparatus including a discharge unit, according to an embodiment. Arrows in FIG. 4 indicate a path along which a discharged drying process fluid moves. In FIG. 4, illustration of the support unit 440 (refer to FIG. 2) is omitted for convenience of description.

Referring to FIG. 4, the discharge unit 550 may include a sampling unit 553, a discharge line 554, and a pressure reducing unit 555. The sampling unit 553 may include a sampling line 551 and a detector 552. The sampling line 551 may branch from a rear end area 554p of the discharge line 554. A first valve 554a may be installed in the discharge line 554, and a second valve 554b may be installed in the sampling line 551. The first valve 554a may be controlled to be opened by a controller 600 when discharge of the drying process fluid inside the processing space 502 is required. The second valve 554b may be controlled to be opened by the controller 600 when introduction of a discharge fluid to the sampling unit 553 is required.

The detector 552 may be installed in the sampling line 551. The detector 552 may collect information of a sampling fluid from a small amount of the drying process fluid. The information of the sampling fluid may mean the concentration, component, and/or number of particles of the sampling fluid. Here, the drying process fluid introduced through the sampling line 551 among the discharged drying process fluid is defined as a sampling fluid. An amount of the sampling fluid may be within about 10% of the total amount of the discharge fluid. For example, the amount of sampling fluid may be within about 0.0001% of the total amount of the discharge fluid. That is, the amount of the sampling fluid may be within about 1 ppm of the total amount of the discharge fluid. The detector 552 may measure the concentration, component, and/or number of particles of the introduced sampling fluid. The discharge fluid may contain a drying process fluid and an object to be detected. The detector 552 may measure the concentration, component, and/or number of particles of remaining objects to be detected except for the drying process fluid in the sampling fluid. The detector 552 may predict an end point of a process, based on information of the object to be detected.

The discharge line 554 includes a front end area 554f and the rear end area 554p. The discharge line 554 between the processing space 502 and the first valve 554a may be referred to as the front end area 554f, and the discharge line 554 excluding the front end area 554f may be referred to as the rear end area 554p. The sampling unit 553 may be arranged to be branched from the rear end area 554p. When the sampling unit 553 is branched from the rear end area 554p, a discharge fluid may be efficiently supplied to the sampling unit 553. In addition, the amount of discharge fluid supplied to the sampling unit 553 may be adjusted by adjusting the second valve 554b.

The remaining discharge fluid, which is not extracted through the sampling line 551, may be discharged to the pressure reducing unit 555 arranged in the rear end area 554p. The pressure reducing unit 555 may include a pressure reducing tank 556. The pressure reducing tank 556 stores the drying process fluid discharged through the discharge line 554 and a dissolved object to be dissolved. A large amount of particles are mixed in the pressure reducing tank 556. Also, as the drying process fluid is vaporized and stored in the pressure reducing tank 556, the solubility of the drying process fluid is reduced, and materials therein are separated.

According to an embodiment, the fluid supply unit 560 may include a third valve 560a installed on the upper branch line 564 and a fourth valve 566a installed on the lower branch line 566. The third valve 560a may be controlled to be opened by the controller 600 when supply of the drying process fluid to an upper portion of the inside of the processing space 502 is required. The fourth valve 566a may be controlled to be opened by the controller 600 when introduction of the drying process fluid to a lower portion of the inside of the processing space 502 is required.

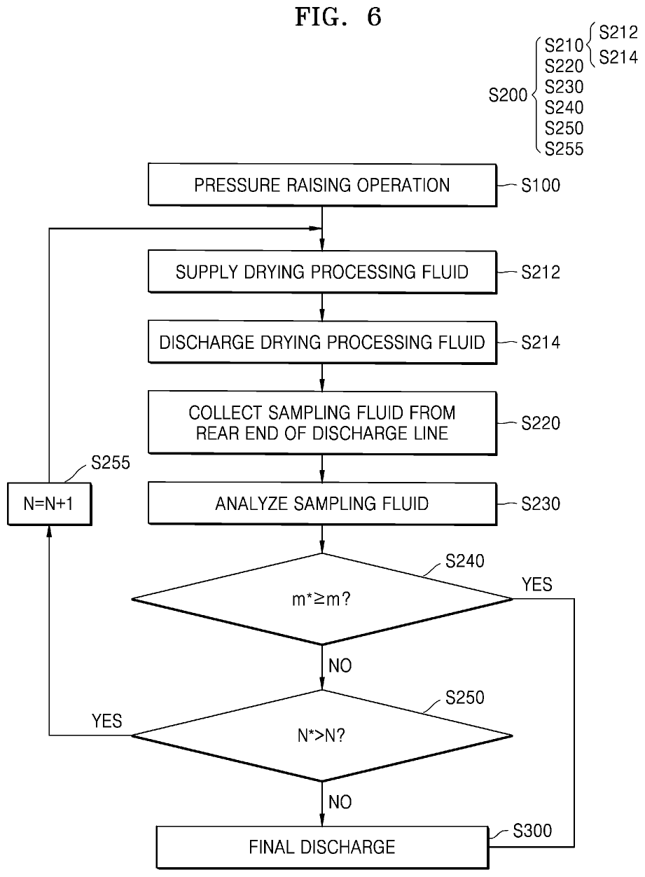

The controller 600 may be electrically connected to the detector 552, the first valve 554a, the second valve 554b, the third valve 560a, and/or the fourth valve 566a to control the operation of each of the detector 552, the first valve 554a, the second valve 554b, the third valve 560a, and/or the fourth valve 566a. For example, the controller 600 may control the first valve 554a to discharge the drying process fluid inside the processing space 502 to the outside of the processing space 502. Also, the controller 600 may control the second valve 554b to allow a portion of discharge fluid to flow into the sampling unit 553. The controller 600 may control the third valve 560a to supply the drying process fluid to the upper portion of the inside of the processing space 502. Also, the controller 600 may control the fourth valve 566a to supply the drying process fluid to the lower portion of the inside of the processing space 502. The controller 600 may control whether the first valve 554a is opened or closed, based on the information of an object to be detected, the information being measured by the detector 552. Also, the controller 600 may control whether the first valve 554a is opened or closed, based on the number of times of injection of the drying process fluid (or the number of times of application of pressure pulses). This will be described below in the description of FIG. 6.

The controller 600 may be implemented in hardware, firmware, software, or any combination thereof. For example, the controller 600 may be a computing device, such as a workstation computer, a desktop computer, a laptop computer, a tablet computer, or the like. For example, the controller 600 may include a memory device, such as read only memory (ROM), random access memory (RAM), or the like, and a processor configured to perform certain operations and algorithms, for example, a microprocessor, a central processing unit (CPU), a graphics processing unit (GPU), or the like. Also, the controller 600 may include a receiver and a transmitter for receiving and transmitting electrical signals, respectively.

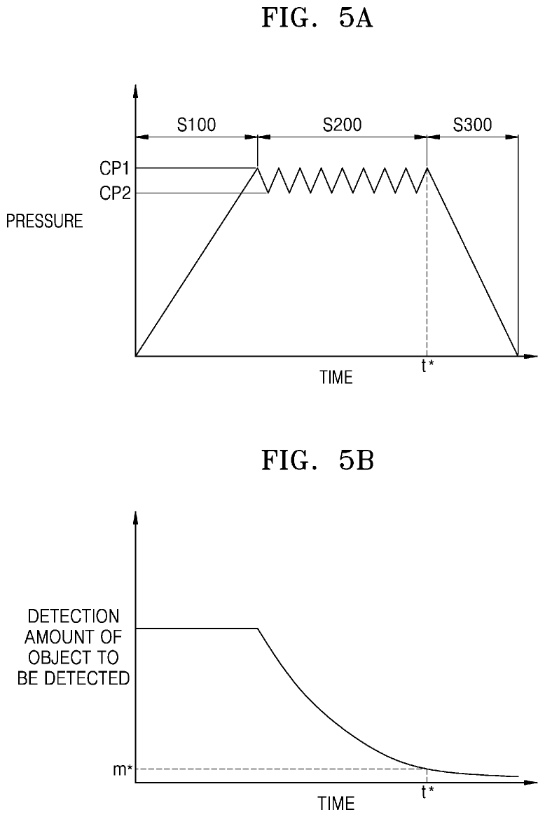

FIGS. 5A and 5B show a graph showing a change in pressure (arbitrary unit, a.u.) over time using a drying process fluid and a graph showing a change in detection amount (a.u.) of an object to be detected over time (a.u.), according to an embodiment.

Referring to FIGS. 3 to 5, a substrate processing process using a drying process fluid may firstly include pressure raising operation S100 (refer to FIG. 6) of increasing an internal pressure of the processing space 502 by supplying the drying process fluid to the processing space 502. In pressure raising operation S100, the inside of the processing space 502 forms a supercritical or higher condition, and then operation S200 (refer to FIG. 6) of repeating supply and discharge of the drying process fluid into and from the processing space 502 is performed. In operation S200, when the supply and discharge of the drying process fluid are repeated, and a detection amount m of an object to be detected reaches an end point t* when a detection amount setting value m* or less is reached, the supply of the drying process fluid is stopped and final discharge S300 (refer to FIG. 6) is performed. The object to be detected may be, for example, an organic solvent or particles dissolved in the drying process fluid.

In more detail, in pressure raising operation S100, the pressure inside the processing space 502 may be increased to a first pressure CP1. Then, in operation S200, the pressure inside the processing space 502 may be repeatedly changed between the first pressure CP1 through supplying the drying process fluid and a second pressure CP2 lower than the first pressure CP1 through discharging through the drying process fluid. Thereafter, in final discharge operation S300, the pressure inside the processing space 502 may decrease. For example, the pressure inside the processing space 502 may change to normal pressure. In operation S200, the pressure inside the processing space 502 is repeated changed, and thus a flow of drying gas in a supercritical state inside the processing space 502 is generated, and the drying gas in the supercritical state may be transferred onto the substrate W.

FIG. 6 is a flowchart illustrating a method of determining an end point of a process by analyzing a sampling fluid, according to an embodiment.

Referring to FIGS. 4 to 6, in pressure raising operation S100, the pressure of the inside of the processing space 502 may be increased. Then, in operation S212 of injecting a drying process fluid, the pressure of the side of the processing space 502 may be increased. Operation S212 of injecting the drying process fluid may be achieved by supplying the drying process fluid to the processing space 502. Then, in operation S214, the drying process fluid and an object to be detected may be discharged, and the pressure of the inside of the processing space 502 may decrease. A fluid including the drying process fluid and the object to be detected may be referred to as discharge fluid. For example, the pressure of the inside of the processing space 502 may be repeatedly changed between the first pressure CP1 and the second pressure CP2 lower than the first pressure CP1. Then, to determine an end point of operation S200, a sampling fluid is collected through the sampling line 551 branched from the rear end area 554p of the discharge line 554 in operation S220. The detector 552 analyzes the collected sampling fluid in operation S230. An organic solvent or particles other than the drying process fluid included in the discharge fluid may be analyzed by the detector 552.

Then, the controller 600 may compare the size of the detection amount m of the object to be detected with the size of the detection amount setting value m*. For example, the detector 552 may measure the mass of an organic solvent dissolved in the drying process fluid or convert the organic solvent into aerosols to measure the number of aerosols, and also vaporize both the drying process fluid and the organic solvent to measure the amount and size of remaining particles. When the detection amount m of the object to be detected is equal to or less than the detection amount setting value m*, the controller 600 may control to end operation S200 and perform final discharge S300.

When the detection amount m of the object to be detected is greater than the detection amount setting value m*, in operation S250, the controller 600 may compare the number of times N of injection of the drying process fluid with a setting number of times N* of injection of the drying process fluid. The initial number of time N of injection of the drying process fluid may be set to one time. When the number of times N of injection of the drying process fluid is equal to or greater than the setting number of times N* of injection of the drying process fluid, the controller 600 may control to end operation S200 and perform final discharge S300. The setting number of times N* of injection of the drying process fluid may be, for example, 8 times, 16 times, 32 times, or the like, and may be variously modified. When the number of times N of injection of the drying process fluid is less than the setting number of times N* of injection of the drying process fluid, 1 is added to the number of times N of injection of the drying process fluid in operation S225, and the above process may be repeated by returning to operation S212 of injecting the drying process fluid.

Because the drying process fluid is in a high-temperature and high-pressure state, manufacturing of an equipment that may directly measure the drying process fluid is limited. Therefore, by using a method of sampling by branching the sampling line 551 in the rear end area 554p of the discharge line 554, according to an embodiment, an end point of an operation may be accurately set, particle analysis of a sampling fluid may be performed, and maintenance may be conveniently performed. Also, as results according to the supply amount and discharge amount of the drying process fluid may be continuously analyzed during the operation, data to establish an optimal condition (a supply amount, a pulse cycle, a discharge amount, a discharge cycle, or the like) may be obtained.

As an embodiment in the detailed description, a process of drying a substrate by using a drying process fluid to remove a pre-processing liquid after liquid-processing the substrate by using the pre-processing liquid including a volatile organic compound has been described in detail, but the disclosure is not limited thereto, and may be applied to all processes using a drying process fluid.

In the detailed description, a method of determining an end point has been described in detail as an embodiment of optimizing a process condition, but the disclosure is not limited thereto, and may be applied to any method that may perform optimization by analyzing a fluid in process.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising:
a body having a processing space configured to pressurize a drying process fluid at a supercritical pressure therein;
a fluid supply unit configured to supply the drying process fluid to the processing space; and
a discharge unit configured to discharge the drying process fluid from inside the processing space,
wherein the discharge unit comprises:
a discharge line coupled to the body; and
a sampling unit comprising a sampling line branched from a rear end area of the discharge line and configured to extract a sampling fluid, and a detector arranged in the sampling line and configured to analyze the sampling fluid.

2. The substrate processing apparatus of claim 1, further comprising a controller configured to control whether the fluid supply unit is operated and whether the discharge unit is operated,
the controller being further configured to receive information about the sampling fluid from the detector to control an operation of each of the fluid supply unit and the discharge unit.

3. The substrate processing apparatus of claim 2, wherein the controller is further configured to stop supply of the drying process fluid and discharge the drying process fluid when a concentration of an object to be detected by the detector is detected to be equal to or less than a set value.

4. The substrate processing apparatus of claim 2, wherein the controller is further configured to stop supply of the drying process fluid and discharge the drying process fluid when the fluid supply unit supplies the drying process fluid a number of times equal to or greater than a set number of times.

5. The substrate processing apparatus of claim 1, wherein the sampling fluid comprises the drying process fluid and an object to be detected,
the detector is further configured to remove the drying process fluid from the sampling fluid and detect the object to be detected.

6. The substrate processing apparatus of claim 5, wherein the detector is further configured to detect at least one of a component, concentration, and number of particles of an object to be detected.

7. The substrate processing apparatus of claim 5, wherein the object to be detected comprises a volatile organic compound.

8. The substrate processing apparatus of claim 1, wherein an amount of the extracted sampling fluid is within 0.0001% of a discharge amount of a discharge fluid discharged through the discharge line.

9. A substrate processing apparatus comprising:
a body having a processing space in which a cleaning processing operation is performed;
a support unit configured to support a substrate inside the processing space;
a fluid supply unit configured to supply a drying process fluid to the processing space;
a discharge unit configured to discharge the drying process fluid inside the processing space; and
a controller configured to control whether the fluid supply unit is operated and whether the discharge unit is operated,
wherein the discharge unit comprises:
a discharge line coupled to the body; and
a sampling unit comprising a sampling line branched from a rear end area of the discharge line and configured to extract a sampling fluid, and a detector arranged in the sampling line and configured to analyze the sampling fluid,
wherein the controller is further configured to:
control to supply the drying process fluid to the processing space, and
control to discharge the drying process fluid from inside the processing space.

10. The substrate processing apparatus of claim 9, wherein the controller is further configured to receive information about the sampling fluid from the detector to control an operation of each of the fluid supply unit and the discharge unit.

11. The substrate processing apparatus of claim 9, wherein the controller is further configured to stop supply of the drying process fluid and discharge the drying process fluid when a concentration of an object to be detected by the detector is detected to be equal to or less than a set value.

12. The substrate processing apparatus of claim 9, wherein the controller is further configured to stop supply of the drying process fluid and discharge the drying process fluid when the fluid supply unit supplies the drying process fluid a number of times equal to or greater than a set number of times.

13. The substrate processing apparatus of claim 9, wherein the detector is further configured to detect at least one of a component, concentration, and number of particles of an object to be detected.

14. The substrate processing apparatus of claim 9, wherein the sampling fluid comprises the drying process fluid and an object to be detected, and
the detector is further configured to remove the drying process fluid from the sampling fluid and detect the object to be detected.

15. The substrate processing apparatus of claim 9, further comprising a first valve at a front end of the discharge line,
wherein the controller opens the first valve when the drying process fluid is discharged.

16. The substrate processing apparatus of claim 9, further comprising a second valve inside the sampling unit,
wherein the controller opens the second valve when a portion of the drying process fluid is introduced into the sampling unit.

17. The substrate processing apparatus of claim 16, wherein the drying process fluid inside the processing space comprises a supercritical fluid.

18. A substrate processing method comprising:
a pressure raising operation of supplying a drying process fluid into a processing space;
an operation of repeating supply and discharge of the drying process fluid with respect to an inside of the processing space;
a final discharge operation of discharging the drying process fluid from inside the processing space; and
a sampling operation of extracting and detecting a portion of the drying process fluid discharged by a sampling unit branched from a rear end area of a discharge line connected to the processing space,
wherein the operation of repeating supply and discharge the drying process fluid is ended and the final discharge operation is started based on information detected by the sampling unit.

19. The substrate processing method of claim 18, wherein the operation of repeating supply and discharge the drying process fluid is ended when a concentration of an object to be detected is detected to be equal to or less than a set value, or when a number of times the drying process fluid is supplied is equal to or greater than a set value.

20. The substrate processing method of claim 18, wherein the sampling operation comprises detecting information about a sampling fluid,
the sampling fluid comprises the drying process fluid and an object to be detected, and
at least one of a component, concentration, and amount of the sampling fluid is detected.
